(19) United States
(12) Patent Application Publication
(10) Pub. No.: US 2018/0342654 A1
(43) Pub. Date: Nov. 29, 2018

(54) ENCAPSULATION STRUCTURE OF MICRO LIGHT-EMITTING DIODE ARRAY SUBSTRATE

(71) Applicant: Shenzhen China Star Optoelectronics Technology Road, Guangming District, Shenzhen City (CN)

(72) Inventor: Lixuan Chen, Shenzhen City (CN)

(21) Appl. No.: 15/548,094

(22) PCT Filed: Jun. 20, 2017
(86) PCT No.: PCT/CN2017/089084

§ 371 Date: Aug. 2, 2017

(30) Foreign Application Priority Data
May 23, 2017 (CN) 201710370182.5

(51) Int. Cl. H01L 33/54; H01L 33/56; H01L 25/075; H01L 33/48; H01L 25/16; H01L 33/60; H01L 33/62

(52) U.S. Cl. CPC H01L 33/54; H01L 33/56; H01L 25/0753; H01L 33/483; H01L 27/1214; H01L 33/60; H01L 33/62; H01L 25/165; H01L 25/167

(57) ABSTRACT

The present invention provides an encapsulation structure of a micro LED array substrate, including a base plate, a micro LED array arranged on the base plate, and a protective layer arranged above the base plate and covering the micro LED array. The micro LED array includes a plurality of micro LEDs arranged in an array. A plurality of recessed cavities are formed in an upper surface of the base plate or a lower surface of the protective layer. The plurality of micro LEDs are received and held in the plurality of recessed cavities. The micro LEDs and drive substrates arranged thereunder can be protected and light emission performance of the micro LED array substrate can be improved.

### BACKGROUND OF THE INVENTION

### 1. Field of the Invention

The present invention relates to the field of display technology, and more particular to an encapsulation structure of a micro light-emitting diode (LED) array substrate.

### 2. The Related Arts

A micro light-emitting diode (LED) is a device having a size between several microns and hundreds of microns. Since it is much smaller than regular LEDs in size, it becomes possible to use a single LED to serve as a pixel for displaying purposes. A micro LED display is a display device that displays an image with a display pixel array that is made up of a high-density arrangement of micro LED array, which, similar to a large scale outdoor LED display panel, allows each of the pixels to be addressable and individually drivable for light emission and can be considered as a miniature version of the outdoor LED display panel, wherein pixel distance is reduced from the order of millimeters to the order of microns. The micro LED display, similar to an organic light-emitting diode (OLED) display, is a self-luminous display, but compared to the OLED display, the micro LED display shows advantages, such as better material stability, extended life span, and being free of burn-in, and is considered the most powerful competitor of the OLED display.

In consideration of lattice match, the micro LED device must be first grown, through molecular beam epitaxy, on a sapphire type supply substrate, and followed by application of laser lift-off (LLO) technology to separate a micro LED bare chip from the supply substrate to be subsequently transferred, through micro transfer print (NTP), to a receiving substrate that is formed, in advance, with a circuit pattern, to form a micro LED array, which can be used to make a micro LED display panel. The basic principle of NTP is generally as follows. A transfer head that comprises a pattern, such as a polydimethylsiloxane (PDMS) transfer head having an embossed structure, is used to pick up, through suction, the micro LED bare chip from the supply substrate by means of a PDMS transfer layer that is adhesive, and then, the PDMS transfer head and the receiving substrate are aligned with each other, followed by having the micro LED bare chip that is picked and held by the PDMS transfer head attached to a predetermined location on the receiving substrate and then having the PDMS transfer head separated from the receiving substrate to complete the transfer of the micro LED bare chip and form a micro LED array substrate. Further, the receiving substrate is a silicon substrate that has been subject to formation of the circuit pattern thereon in advance and may be a flexible one or a rigid one.

In the known processes for manufacturing micro LED display panels, to provide protection to micro LEDs and a drive substrate located thereunder and also for improving an effect of light emission of the micro LED array, it is desired to provide a novel encapsulation structure of a micro LED array substrate, this being one of the technical issues that have been long desired to solve.

### SUMMARY OF THE INVENTION

An objective of the present invention is to provide an encapsulation structure of a micro light-emitting diode (LED) array substrate, which helps protect micro LEDs and a drive substrate located thereunder and also improves an effect of light emission of the micro LED array substrate.

To achieve the above objective, the present invention provides an encapsulation structure of a micro LED array substrate, which comprises a base plate, a micro LED array arranged on the base plate, and a protective layer arranged above the base plate and covering the micro LED array;

wherein the micro LED array comprises a plurality of micro LEDs arranged in an array; and

a plurality of recessed cavities is formed in an upper surface of the base plate or a lower surface of the protective layer, the plurality of micro LEDs being received in the plurality of recessed cavities.

Optionally, the plurality of recessed cavities are arranged in the upper surface of the base plate and the protective layer comprises a board made of glass or plastics, and the protective layer has a thickness greater than 1 mm.

Optionally, the encapsulation structure of the micro LED array substrate further comprises a plurality of support pillars arranged between the base plate and the protective layer. The plurality of support pillars are provided on the base plate to support the protective layer.

Optionally, the plurality of recessed cavities is arranged in the upper surface of the base plate and the protective layer comprises an organic film formed on the base plate through coating.

The plurality of recessed cavities and the plurality of micro LEDs are arranged in a one-to-one corresponding manner and each of the recessed cavities has a depth that is greater than a height of the micro LED received therein.

Each of the recessed cavities has a sidewall that is provided with a reflective layer attached thereto.

Optionally, the plurality of recessed cavities are arranged in the lower surface of the protective layer and the protective layer comprises a board made of glass or plastics. The protective layer has a thickness greater than 1 mm.

The plurality of recessed cavities are formed in the lower surface of the protective layer through laser perforation or impression; and

the recessed cavities each have a sidewall having an arc configuration, the recessed cavities having an opening that has a circular shape or an elliptic shape.

Each of the recessed cavities corresponds to and covers a single one or multiple ones of the micro LEDs.

The base plate comprises a thin-film transistor (TFT) array substrate.

The present invention also provides an encapsulation structure of a micro LED array substrate, which comprises a base plate, a micro LED array arranged on the base plate, and a protective layer arranged above the base plate and covering the micro LED array;

wherein the micro LED array comprises a plurality of micro LEDs arranged in an array; and

a plurality of recessed cavities is formed in an upper surface of the base plate or a lower surface of the protective layer, the plurality of micro LEDs being received in the plurality of recessed cavities;

wherein the plurality of recessed cavities are arranged in the upper surface of the base plate and the protective layer comprises a board made of glass or plastics, the protective layer having a thickness greater than 1 mm; and

wherein the base plate comprises a thin-film transistor (TFT) array substrate.

The efficacy of the present invention is that the present invention provides an encapsulation structure of a micro LED array substrate, which comprises a base plate, a micro LED array arranged on the base plate, and a protective layer arranged above the base plate and covering the micro LED array. The micro LED array comprises a plurality of micro LEDs arranged in an array. A plurality of recessed cavities are formed in an upper surface of the base plate or a lower surface of the protective layer. The plurality of micro LEDs are received and held in the plurality of recessed cavities. The micro LEDs and drive substrates arranged thereunder can be protected and light emission performance of the micro LED array substrate can be improved.

### BRIEF DESCRIPTION OF THE DRAWINGS

For better understanding of the features and technical contents of the present invention, reference will be made to the following detailed description of the present invention and the attached drawings. However, the drawings are provided only for reference and illustration and are not intended to limit the present invention.

In the drawings:

FIG. 1 is a schematic view illustrating a first embodiment of an encapsulation structure of a micro light-emitting diode (LED) array substrate according to the present invention;

FIG. 2 is a schematic view illustrating a second embodiment of the encapsulation structure of the micro LED array substrate according to the present invention;

FIG. 3 is a schematic view illustrating a third embodiment of the encapsulation structure of the micro LED array substrate according to the present invention;

FIG. 4 is a schematic view illustrating a fourth embodiment of the encapsulation structure of the micro LED array substrate according to the present invention;

FIG. 5 is a schematic view illustrating an arrangement of a plurality of cavities in a protection layer of the fourth embodiment of the encapsulation structure of the array substrate according to the present invention; and

FIG. 6 is a schematic view illustrating a fifth embodiment of the encapsulation structure of the micro LED array substrate according to the present invention.

### DETAILED DESCRIPTION OF THE PREFERRED EMBODIMENTS

To further expound the technical solution adopted in the present invention and the advantages thereof, a detailed description will be given with reference to the preferred embodiments of the present invention and the drawings thereof.

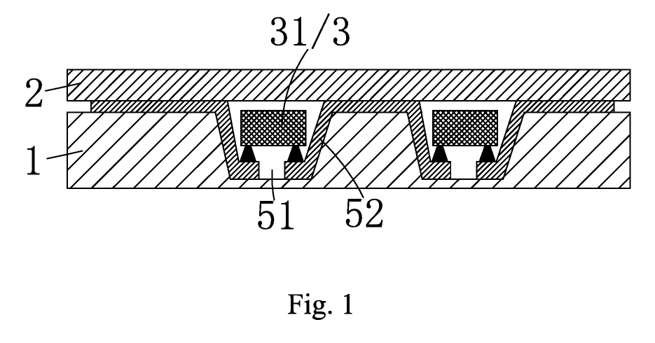

Referring to FIG. 1, FIG. 1 is a schematic view illustrating a first embodiment of an encapsulation structure of a micro light-emitting diode (LED) array substrate according to the present invention. In the instant embodiment, the encapsulation structure of the micro LED array substrate comprises a base plate 1, a micro LED array 3 arranged on the base plate 1, and a protective layer 2 arranged above the base plate 1 and covering the micro LED array 3.

The micro LED array 3 comprises a plurality of micro LEDs 31 arranged in an array.

The base plate 1 has an upper surface in which a plurality of recessed cavities 51 is formed. The plurality of micro LEDs 31 are respectively received and held in the plurality of recessed cavities 51.

Specifically, in the instant embodiment, the protective layer 2 comprises a glass board, a plastic board, or a board made of other materials, and the protective layer 2 provides a function of serving as an encapsulation cover plate. For example, the protective layer 2 can be a board of polyethylene terephthalate (PET), polycarbonate (PC), or polymethacrylate (PMA).

Preferably, the protective layer 2 has a thickness greater than 1 mm.

Specifically, each of the recessed cavities 51 has a sidewall that is provided with a reflective layer 52 attached thereto so as to reflect light emitting from the micro LED 31 to thereby effectively increase light emission efficiency of the micro LED array substrate.

Specifically, the plurality of recessed cavities 51 and the plurality of micro LEDs 31 are arranged in a one-to-one corresponding manner.

Preferably, each of the recessed cavities 51 has a depth that is greater than a height of the micro LED 31 received therein. In other words, each of the micro LEDs 31 is completely sunk in the corresponding one of the recessed cavities 51 so as to facilitate the arrangement of the protective layer 2 on or above the base plate 1 to realize encapsulation of the micro LED array substrate.

Specifically, the base plate 1 is a thin-film transistor (TFT) array substrate in order to drive the micro LED array 3 arranged thereon so that the micro LED array substrate, after the encapsulation, can be used in fabrication of a micro LED display.

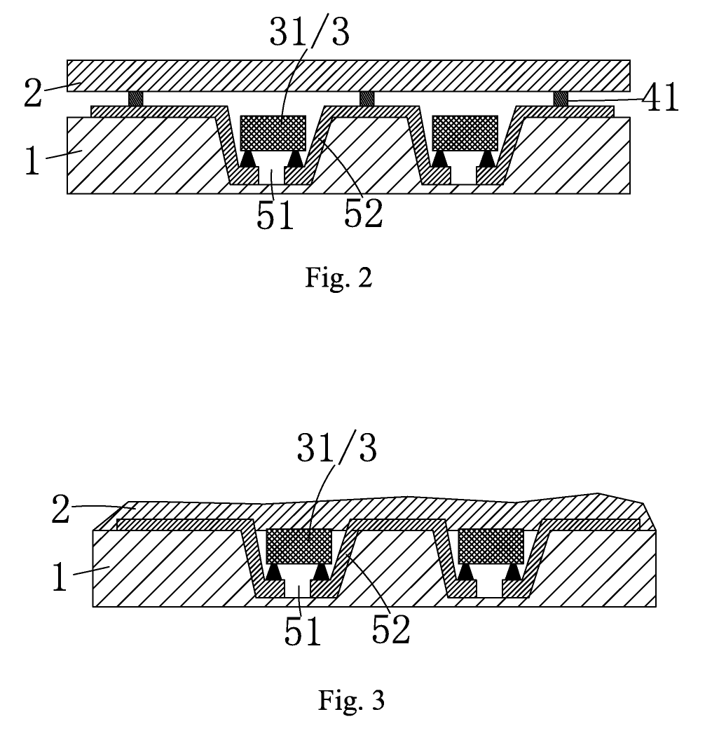

Referring to FIG. 2, FIG. 2 is a schematic view illustrating a second embodiment of the encapsulation structure of the micro LED array substrate according to the present invention. Compared to the first embodiment described above, the instant embodiment provides an encapsulation structure of a micro LED array substrate, which further comprises a plurality of support pillars 41 arranged between the base plate 1 and the protective layer 2. The plurality of support pillars 41 are provided on the base plate 1 to support the protective layer 2 thereon. The remaining features are similar to those of the first embodiment and repeated description will be omitted herein.

Referring to FIG. 3, FIG. 3 is a schematic view illustrating a third embodiment of the encapsulation structure of the micro LED array substrate according to the present invention. Compared to the first embodiment described above, the instant embodiment provides a protective layer 2 that comprises a layer of an organic film formed on the base plate 1 through a coating process. For example, the protective layer 2 can be a layer of a film made of a material of polyfluoroalkoxy (PFA), which is formed on the base plate 1 through coating and solidifying processes.

Specifically, in the instant embodiment, the protective layer 2 has a thickness that meets the requirement of covering the plurality of micro LEDs 31 and no specific constraint is imposed for the thickness. The remaining features are similar to those of the first embodiment and repeated description will be omitted herein.

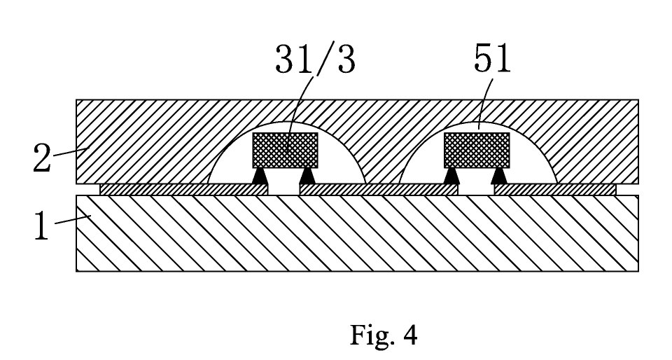

Referring to FIG. 4, FIG. 4 is a schematic view illustrating a fourth embodiment of the encapsulation structure of the micro LED array substrate according to the present invention. Compared to the first embodiment, the instant embodiment provides a plurality of recessed cavities 51 formed in a lower surface of the protective layer 2.

Specifically, in the instant embodiment, the recessed cavities 51 each have a sidewall that has an arc configuration and an opening of each of the recessed cavities 51 can be of various shapes, such as a circular shape or an elliptic shape. Since there is a difference of refractive index between the glass or plastic material of the protective layer 2 and a medium (such as air) contained in the recessed cavities 51, the recessed cavities 52 each provide an effect of focusing light emitting from the micro LED 31 covered thereby so as to suitably improve the light emission efficiency of the micro LED array substrate.

Specifically, the plurality of recessed cavities 51 are formed in the lower surface of the protective layer 2 through laser perforation or impression.

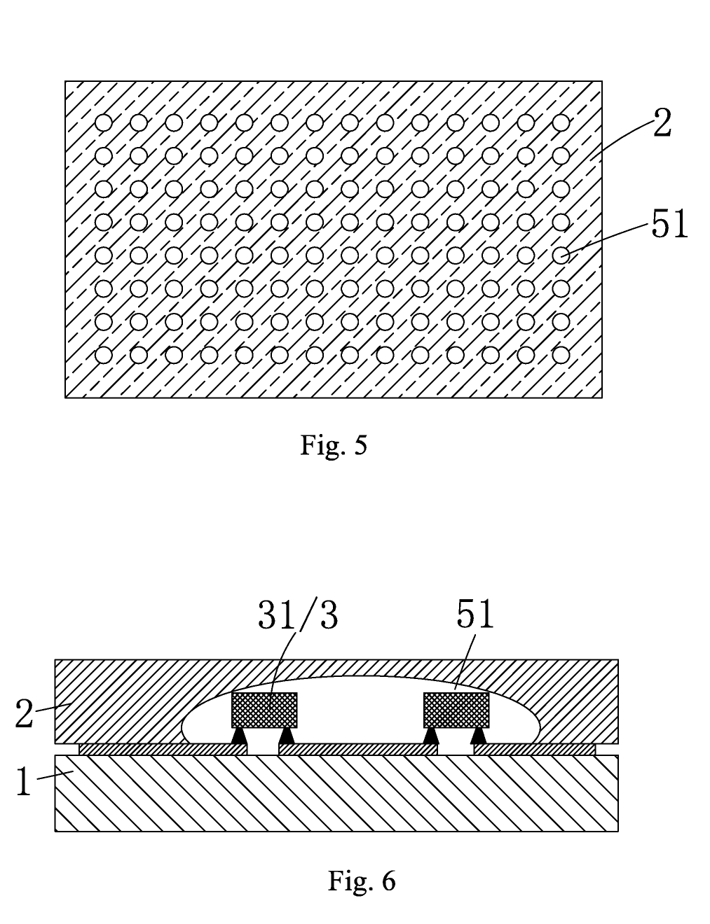

Specifically, as shown in FIG. 5, the plurality of recessed cavities 51 and the plurality of micro LEDs 31 are arranged on the lower surface of the protective layer 2 to form an arrangement of an array and the recessed cavities 51 are arranged such that an opening diameter thereof is greater than a length of the micro LED 31. Each of the recessed cavities 51 may cover single one or multiple ones of the micro LEDs 31. Specifically, in the instant embodiment, each of the recessed cavities 51 covers one single micro LED 31. The remaining features are similar to those of the fourth embodiment described above and repeated description will be omitted herein.

Referring to FIG. 6, FIG. 6 is a schematic view illustrating a fifth embodiment of the encapsulation structure of the micro LED array substrate according to the present invention. Compared to the fourth embodiment described above, the instant embodiment is such that, specifically speaking, each of the recessed cavities 51 corresponds to and covers two micro LEDs 31, and accordingly, the recessed cavities 51 are each arranged such that an opening diameter thereof is greater a length of two micro LEDs 31. The remaining features are similar to those of the fourth embodiment described above and repeated description will be omitted herein.

In summary, the present invention provides an encapsulation structure of a micro LED array substrate, which comprises a base plate, a micro LED array arranged on the base plate, and a protective layer arranged above the base plate and covering the micro LED array. The micro LED array comprises a plurality of micro LEDs arranged in an array. A plurality of recessed cavities are formed in an upper surface of the base plate or a lower surface of the protective layer. The plurality of micro LEDs are received and held in the plurality of recessed cavities. The micro LEDs and drive substrates arranged thereunder can be protected and light emission performance of the micro LED array substrate can be improved.

Based on the description given above, those having ordinary skills in the art may easily contemplate various changes and modifications of the technical solution and the technical ideas of the present invention. All these changes and modifications are considered belonging to the protection scope of the present invention as defined in the appended claims.

1. An encapsulation structure of a micro light-emitting diode (LED) array substrate, comprising a base plate, a micro LED array arranged on the base plate, and a protective layer arranged above the base plate and covering the micro LED array;
wherein the micro LED array comprises a plurality of micro LEDs arranged in an array; and
a plurality of recessed cavities is formed in a lower surface of the protective layer, the plurality of micro LEDs being received in the plurality of recessed cavities.

2. The encapsulation structure of the micro LED array substrate as claimed in claim 1, wherein the plurality of recessed cavities are arranged in the upper surface of the base plate and the protective layer comprises a board made of glass or plastics, the protective layer having a thickness greater than 1 mm.

3. The encapsulation structure of the micro LED array substrate as claimed in claim 2 further comprising a plurality of support pillars arranged between the base plate and the protective layer, the plurality of support pillars being provided on the base plate to support the protective layer.

4. The encapsulation structure of the micro LED array substrate as claimed in claim 1, wherein the plurality of recessed cavities is arranged in the upper surface of the base plate and the protective layer comprises an organic film formed on the base plate through coating.

5. The encapsulation structure of the micro LED array substrate as claimed in claim 2, wherein the plurality of recessed cavities and the plurality of micro LEDs are arranged in a one-to-one corresponding manner and each of the recessed cavities has a depth that is greater than a height of the micro LED received therein.

6. The encapsulation structure of the micro LED array substrate as claimed in claim 2, wherein each of the recessed cavities has a sidewall that is provided with a reflective layer attached thereto.

7. The encapsulation structure of the micro LED array substrate as claimed in claim 1, wherein the protective layer comprises a board made of glass or plastics, the protective layer having a thickness greater than 1 mm.

8. The encapsulation structure of the micro LED array substrate as claimed in claim 7, wherein the plurality of recessed cavities are formed in the lower surface of the protective layer through laser perforation or impression; and
the recessed cavities each have a sidewall having an arc configuration, the recessed cavities having an opening that has a circular shape or an elliptic shape.

9. The encapsulation structure of the micro LED array substrate as claimed in claim 7, wherein each of the recessed cavities corresponds to and covers a single one or multiple ones of the micro LEDs.

10. The encapsulation structure of the micro LED array substrate as claimed in claim 1, wherein the base plate comprises a thin-film transistor (TFT) array substrate.

11. An encapsulation structure of a micro light-emitting diode (LED) array substrate, comprising a base plate, a micro LED array arranged on the base plate, and a protective layer arranged above the base plate and covering the micro LED array;
wherein the micro LED array comprises a plurality of micro LEDs arranged in an array; and
a plurality of recessed cavities is formed in an upper surface of the base plate or a lower surface of the protective layer, the plurality of micro LEDs being received in the plurality of recessed cavities;
wherein the plurality of recessed cavities are arranged in the upper surface of the base plate and the protective layer comprises a board made of glass or plastics, the protective layer having a thickness greater than 1 mm; and
wherein the base plate comprises a thin-film transistor (TFT) array substrate.

12. The encapsulation structure of the micro LED array substrate as claimed in claim 11 further comprising a plurality of support pillars arranged between the base plate and the protective layer, the plurality of support pillars being provided on the base plate to support the protective layer.

13. The encapsulation structure of the micro LED array substrate as claimed in claim 11, wherein the plurality of recessed cavities and the plurality of micro LEDs are arranged in a one-to-one corresponding manner and each of the recessed cavities has a depth that is greater than a height of the micro LED received therein.

14. The encapsulation structure of the micro LED array substrate as claimed in claim 11, wherein each of the recessed cavities has a sidewall that is provided with a reflective layer attached thereto.
